(19) United States
(12) Patent Application Publication
(10) Pub. No.: US 2026/0266592 A1
(43) Pub. Date: Sep. 10, 2026

(54) MARK POSITION MEASUREMENT APPARATUS AND MARK POSITION MEASUREMENT METHOD

(71) Applicant: NuFlare Technology, Inc., Yokohama-shi (JP)

(72) Inventor: Hiroshi SATO, Utsunomiya-shi (JP)

(73) Assignee: NuFlare Technology, Inc., Yokohama-shi (JP)

(21) Appl. No.: 19/663,566

(22) Filed: Apr. 30, 2026

Related U.S. Application Data
(63) Continuation of application No. PCT/JP2024/039644, filed on Nov. 7, 2024.

(30) Foreign Application Priority Data
Nov. 17, 2023 (JP) 2023-195650

(51) Int. Cl. G01B 11/06; G01B 11/00; G03F 7/00; G03F 9/00

(52) U.S. Cl. CPC G01B 11/0608; G01B 11/002; G03F 7/704; G03F 9/7049; G03F 9/7065; G03F 9/7092; G03F 9/7096

(57) ABSTRACT

According to one aspect of the present invention, a mark position measurement apparatus includes a mark position calculation circuit configured to calculate, in a state where the height position of the target object has been controlled to be the predetermined height position, positions of marks by using change of a signal for a mark of the marks due to a state of a surface of the target object, obtained by the sensor by scanning the laser beam over the marks such that the laser beam intersects the marks, and a positional deviation amount calculation circuit configured to calculate a positional deviation amount deviated from a calculated position of a mark concerned of the marks, by using an incident angle of the laser beam, and surface height positions of the target object at the positions of the marks acquired from the height position distribution of the surface of the target object.

### CROSS-REFERENCE TO RELATED APPLICATION

This application is a continuation application based upon and claims the benefit of priority from prior Japanese Patent Application No. 2023-195650 (application number) filed on Nov. 17, 2023 in Japan, and International Application PCT/JP2024/039644, the International Filing Date of which is Nov. 7, 2024. The contents described in JP2023-195650 and PCT/JP2024/039644 are incorporated herein by reference.

### BACKGROUND OF THE INVENTION

### Field of the Invention

An embodiment of the present invention relates to a mark position measurement apparatus, and a mark position measurement method. For example, it relates to a method for measuring a position of an alignment mark on a writing target object.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is becoming increasingly finer year by year. The electron beam writing technique, which intrinsically has excellent resolution, is used for writing or “drawing” on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple beam system forms multiple beams by letting an electron beam emitted from an electron gun pass through a mask having a plurality of holes, performs blanking control for each beam, reduces each unblocked beam by an optical system, and deflects, by a deflector, a reduced beam to be applied to a desired position on a target object or “sample”.

In electron beam writing including multiple beam writing, when a writing target substrate is disposed on the stage, an alignment mark formed on the substrate is detected with an electron beam. Then, using a detected alignment mark as a reference, alignment of a writing region is performed.

Alignment marks of recent date are formed with a finer line width (critical dimension) compared with conventional alignment marks. Therefore, when a mark is irradiated with an electron beam, the electron yield is too small to achieve good contrast. As a result, there is a problem that the SN ratio is low, and therefore, alignment marks on the target object 101 cannot be found easily. To cope with this problem, it is examined to increase the dose (irradiation amount) of an electron beam in order to obtain contrast. However, if this method is employed, a high-dose electron beam is applied to resist in a large area, resulting in a problem that the resist is scattered to contaminate the inside of the chamber.

There is disclosed a method in which a cross mark whose reflectance is different from that of the environment is formed on the surface of a target object, and the position of the cross mark is measured based on a change of a light reception amount obtained by scanning the cross mark by a Z sensor, and in which the height position of the cross mark is measured by the Z sensor, and if the height position of the cross mark is deviated from the normal height, the error of the measurement position of the cross mark occurring from the height deviation is corrected (e.g., refer to Japanese Patent Application Laid-open (JP-A) No. 2010-074110). However, there is a case where the accuracy of the mark position measured by the Z sensor is insufficient. Furthermore, according to this method, it is necessary to perform a step of separately measuring the height position of the mark, for checking whether a positional deviation exists or not and for correcting a deviation when it exists.

### BRIEF SUMMARY OF THE INVENTION

According to one aspect of the present invention, a mark position measurement apparatus includes
a movable stage configured to mount thereon a target object on which a plurality of marks are formed,
a sensor configured to include an irradiator which irradiates the target object with a laser beam, and a receiver which receives a reflected light from the target object irradiated with the laser beam and outputs a signal relating to a height position of an irradiated position on a surface of the target object,
a height position distribution acquisition circuit configured to acquire, in a state where the height position of the target object has been controlled to be a predetermined height position, a height position distribution of the surface of the target object, based on a result obtained by the sensor,
a mark position calculation circuit configured to calculate, in a state where the height position of the target object has been controlled to be the predetermined height position, positions of the plurality of marks by using change of a signal for a mark of the plurality of marks due to a state of a surface of the target object, obtained by the sensor by scanning the laser beam over the plurality of marks such that the laser beam intersects the plurality of marks,
a positional deviation amount calculation circuit configured to calculate a positional deviation amount deviated from a calculated position of a mark concerned of the plurality of marks, by using an incident angle of the laser beam, and surface height positions of the target object at the positions of the plurality of marks acquired from the height position distribution of the surface of the target object, and
a correction circuit configured to correct, for the plurality of marks, the calculated position of the mark concerned by using a positional deviation amount concerned in a plurality of calculated positional deviation amounts.

According to another aspect of the present invention, a mark position measurement apparatus includes
a movable stage configured to mount thereon a target object on which a plurality of marks are formed,
a sensor configured to include an irradiator which irradiates the target object with a laser beam and a receiver which receives a reflected light from the target object irradiated with the laser beam and outputs a signal relating to a height position of an irradiated position on a surface of the target object,
a height position calculation circuit configured to calculate a first height position by using height position information, obtained by the sensor, on each position of positions where it is assumed that the plurality of marks exist,
a mark position calculation circuit configured to calculate, in a state where the height position of the target object has been controlled such that the first height position becomes a reference height position, positions of the plurality of marks by using change of a signal for a mark of the plurality of marks due to a state of a surface of the target object, obtained by the sensor by scanning the laser beam over the plurality of marks such that the laser beam intersects the plurality of marks, and
a control circuit configured to control, in order to write a pattern on the target object with a charged particle beam, the height position of the target object such that a second height position, which is set for writing, becomes the reference height position.

According to yet another aspect of the present invention, a mark position measurement method includes
measuring, in a state where a height position of a target object, on which a plurality of marks are formed, mounted on a stage has been controlled to be a predetermined height position, height positions of a surface of the target object by a sensor including an irradiator which irradiates the target object with a laser beam and a receiver which receives a reflected light from the target object irradiated with the laser beam and outputs a signal relating to a height position of an irradiated position on the surface of the target object,
acquiring, a height position distribution of the surface of the target object, based on a result measured by the sensor,
calculating, in a state where the height position of the target object has been controlled to be the predetermined height position, positions of the plurality of marks by using change of a signal for a mark of the plurality of marks due to a state of a surface of the target object, obtained by the sensor by scanning the laser beam over the plurality of marks such that the laser beam intersects the plurality of marks,
calculating a positional deviation amount deviated from a calculated position of a mark concerned of the plurality of marks, by using an incident angle of the laser beam, and surface height positions of the target object at the positions of the plurality of marks acquired from the height position distribution of the surface of the target object, and
correcting, for the plurality of marks, the calculated position of the mark concerned by using a positional deviation amount concerned in a plurality of calculated positional deviation amounts, and outputting a corrected position of the mark concerned.

According to yet another aspect of the present invention, a mark position measurement method includes
measuring height position information on each position of positions, where it is assumed that a plurality of marks exist, on a target object which is mounted on a stage and on which the plurality of marks are formed, by a sensor including an irradiator which irradiates the target object with a laser beam and a receiver which receives a reflected light from the target object irradiated with the laser beam and outputs a signal relating to a height position of an irradiated position on a surface of the target object,
calculating a first height position by using the height position information, obtained by the sensor, on the each position of the positions where it is assumed that the plurality of marks exist,
calculating, in a state where a height position of the target object has been controlled such that the first height position becomes a reference height position, positions of the plurality of marks by using change of a signal for a mark of the plurality of marks due to a state of a surface of the target object, obtained by the sensor by scanning the laser beam over the plurality of marks such that the laser beam intersects the plurality of marks, and outputting calculated positions of the plurality of marks, and
controlling, in order to write a pattern on the target object with a charged particle beam, the height position of the target object such that a second height position, which is set for writing, becomes the reference height position.

### BRIEF DESCRIPTION OF THE DRAWINGS

FIG. 1 is a schematic diagram showing a configuration of a writing apparatus according to a first embodiment;

FIG. 2 is a conceptual diagram showing an example of a configuration of a shaping aperture array substrate according to the first embodiment;

FIG. 3 is a sectional view showing an example of a configuration of a blanking aperture array mechanism according to the first embodiment;

FIG. 4 is a top view showing an example of a configuration of a target object according to the first embodiment;

FIG. 5 is a sectional view showing an example of a configuration of an alignment mark according to the first embodiment;

FIG. 6 is a sectional view showing an example of a configuration of an alignment mark according to the first embodiment;

FIG. 7 is an illustration for explaining an error in the case of measuring a mark position by a Z sensor according to the first embodiment;

FIG. 8 is a flowchart showing an example of main steps of a writing method according to the first embodiment;

FIG. 9 is an illustration for explaining a stage mechanism and a writing height position according to the first embodiment;

FIG. 10 is an illustration showing an example of a height measurement position in the surface of a target object according to the first embodiment;

FIG. 11 is an illustration explaining a method of roughly searching for a mark according to the first embodiment;

FIG. 12 is an illustration for explaining a measurement principle of a Z sensor according to the first embodiment;

FIG. 13 is an illustration showing an example of an intensity distribution of a laser beam used by a Z sensor according to the first embodiment;

FIG. 14 is a sectional view showing an example of the state of an irradiation light in the case of scanning an alignment mark by a Z sensor according to the first embodiment;

FIG. 15 is a sectional view showing an example of the state of a reflected light in the case of scanning an alignment mark by a Z sensor according to the first embodiment;

FIG. 16 is an illustration showing an example of a height position distribution of a concave-convex mark according to the first embodiment;

FIG. 17 is an illustration showing an example of a height position distribution according to the first embodiment;

FIG. 18 is a conceptual diagram showing an example of a writing operation according to the first embodiment;

FIG. 19 is an illustration showing an example of an irradiation region of multiple beams and a writing target pixel according to the first embodiment;

FIG. 20 is an illustration explaining an example of a multi-beam writing operation according to the first embodiment;

FIG. 21 is an illustration showing an example of surface height positions of a target object in the vicinity of a mark position including the mark position itself according to a second embodiment;

FIG. 22 is a flowchart showing an example of main steps of a writing method according to a third embodiment; and

FIG. 23 is an illustration for explaining a stage mechanism, and a height position for searching for a mark according to the third embodiment.

### DETAILED DESCRIPTION OF THE INVENTION

Embodiments of the present invention provide an apparatus and method that can highly accurately measure positions of a plurality of marks formed on a target object.

Embodiments below describe a configuration using an electron beam as an example of a charged particle beam. The charged particle beam is not limited to the electron beam, and other charged particle beams such as an ion beam may also be used. Embodiments below describe a writing apparatus using multiple beams. However, it is not limited thereto, and is also preferable to employ a writing apparatus using a single beam. For example, embodiments can be applied to a variable shaped beam (VSB) type writing apparatus.

### First Embodiment

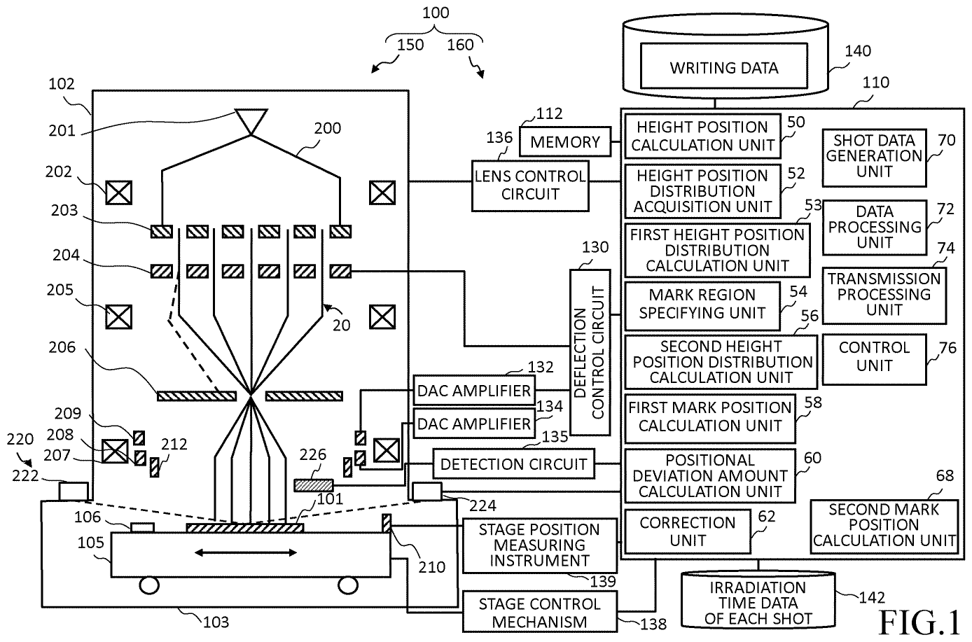

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multi-charged particle beam writing apparatus and a multi-charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an objective lens 207, deflectors 208 and 209, an electrostatic lens 212, and a detector 226.

In the writing chamber 103, a stage 105 is disposed. On the stage 105, there is placed a target object or “sample” 101 such as a mask serving as a writing target substrate when writing (exposure) is performed. The target object 101 is, for example, an exposure mask used in fabricating semiconductor devices, or a semiconductor substrate (silicon wafer) for fabricating semiconductor devices. Furthermore, the target object 101 may be, for example, a mask blank on which a resist has been applied and nothing has yet been written. On target object 101, a plurality of alignment marks (concave-convex marks) whose concave (recessed) surface and convex (projected) surface are made of the same material, to be described later, are formed.

On the stage 105, a mirror 210 for measuring the position of the stage 105 is arranged. Furthermore, on the stage 105, a mark stand 106 is arranged. A pattern, such as a cross mark, is formed on the surface of the mark stand 106, for example. The surface height of the mark stand 106 is used as a reference height.

On the writing chamber 103, a Z sensor 220 (an example of a sensor) is disposed. The Z sensor 220 includes, for example, an irradiator 222 which generates a visible laser beam, and a photoreceiver 224 which receives a reflected light from a target object irradiated with the laser beam. The irradiator 222 generates a laser beam in oblique incidence on the surface of the target object 101 arranged on the stage 105 in the writing chamber 103. Thus, the irradiator 222 irradiates the target object 101 with laser beams. The laser beam emitted from the irradiator 222 has a light intensity distribution of normal distribution. Furthermore, the laser beam emitted from the irradiator 222 has a diameter larger than the width of the alignment mark formed on the target object 101. This is due to the beam diameter at the emission, and the optical element for guiding beams, and is largely affected by the phenomenon that the beam extends in an incident direction because of the oblique incidence on the target object. For example, a laser beam with a diameter of 10 to 300 μm on the surface of the target object 101 is used. For example, it is preferable to use a laser beam with a diameter of about 200 μm on the surface of the target object 101. The photoreceiver 224 receives a reflected light from the target object 101 due to irradiation of a laser beam, and outputs a signal relating to the height position of the irradiated position on the surface of the target object 101. As the photoreceiver 224, an optical position sensor is used, for example. The photoreceiver 224 receives a reflected light, measures the height position of the surface of the target object 101 based on a deviation of the light-receiving position on the surface which received the light, and outputs information on the measured position.

The control system circuit 160 includes a control computer 110, a memory 112, a deflection control circuit 130, digital-analog converter (DAC) amplifier units 132 and 134, a detection circuit 135, a lens control circuit 136, a stage control mechanism 138, a stage position measuring instrument 139, and storage devices 140 and 142 such as magnetic disk drives. The control computer 110, the memory 112, the deflection control circuit 130, the detection circuit 135, the lens control circuit 136, the stage control mechanism 138, the stage position measuring instrument 139, and the storage devices 140 and 142 are connected to each other through a bus (not shown). The DAC amplifier units 132 and 134 and the blanking aperture array mechanism 204 are connected to the deflection control circuit 130. The deflector 209 is composed of at least four electrodes (or “at least four poles”), and controlled by the deflection control circuit 130 through the DAC amplifier unit 132 disposed for each electrode. The deflector 208 is composed of at least four electrodes (or “at least four poles”), and controlled by the deflection control circuit 130 through the DAC amplifier unit 134 disposed for each electrode. Electromagnetic lenses such as the illumination lens 202, the reducing lens 205, and the objective lens 207 are controlled by the lens control circuit 136. The detector 226 is connected to the detection circuit 135. The electrostatic lens 212 is controlled by an electrostatic lens control circuit (not shown).

The position of the stage 105 is controlled by the drive of each axis motor (not shown) which is controlled by the stage control mechanism 138. Based on the principle of laser interferometry, the stage position measuring instrument 139 measures the position of the stage 105 by receiving a reflected light from the mirror 210.

In the control computer 110, there are arranged a height position calculation unit 50, a height position distribution acquisition unit 52, a first height position distribution calculation unit 53, a mark region specifying unit 54, a second height position distribution calculation unit 56, a first mark position calculation unit 58, a positional deviation amount calculation unit 60, a correction unit 62, a second mark position calculation unit 68, a shot data generation unit 70, a data processing unit 72, a transmission processing unit 74, and a control unit 76. Each of the “ . . . units” such as the height position calculation unit 50, the height position distribution acquisition unit 52, the first height position distribution calculation unit 53, the mark region specifying unit 54, the second height position distribution calculation unit 56, the first mark position calculation unit 58, the positional deviation amount calculation unit 60, the correction unit 62, the second mark position calculation unit 68, the shot data generation unit 70, the data processing unit 72, the transmission processing unit 74, and the control unit 76 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the height position calculation unit 50, the height position distribution acquisition unit 52, the first height position distribution calculation unit 53, the mark region specifying unit 54, the second height position distribution calculation unit 56, the first mark position calculation unit 58, the positional deviation amount calculation unit 60, the correction unit 62, the second mark position calculation unit 68, the shot data generation unit 70, the data processing unit 72, the transmission processing unit 74, and the control unit 76, and information being operated are stored in the memory 112 each time.

Writing operations of the writing apparatus 100 are controlled by the control unit 76. Processing of transmitting irradiation time data of each shot to the deflection control circuit 130 is controlled by the transmission processing unit 74.

Writing data (chip data) is input from the outside of the writing apparatus 100, and stored in the storage device 140. Chip data defines information on a plurality of figure patterns configuring a chip pattern. Specifically, for example, for each figure pattern, coordinates for each vertex are defined in the order of configuration of the figure. Alternatively, for example, for each figure pattern, a figure code, coordinates, a size, and the like are defined.

FIG. 1 shows a configuration necessary for describing the first embodiment. Other configuration elements generally necessary for the writing apparatus 100 may also be included therein.

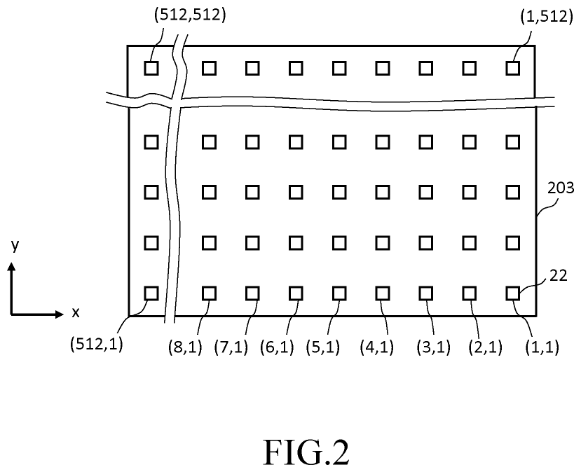

FIG. 2 is a conceptual diagram showing an example of a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes (openings) 22 of 512×512, that is 512 (holes arrayed in the y direction)×512 (holes arrayed in the x direction), are formed. The number of holes 22 is not limited thereto. For example, it is also preferable to form the holes 22 of 32×32. Each of the holes 22 is a rectangle having the same dimension and shape as each other. Alternatively, each of the holes 22 may be a circle with the same diameter as each other. Multiple beams 20 are formed by letting portions of an electron beam 200 individually pass through a corresponding one of a plurality of holes 22. In other words, the shaping aperture array substrate 203 forms and emits the multiple beams 20. The shaping aperture array substrate 203 is an example of an emission source of the multiple beams 20.

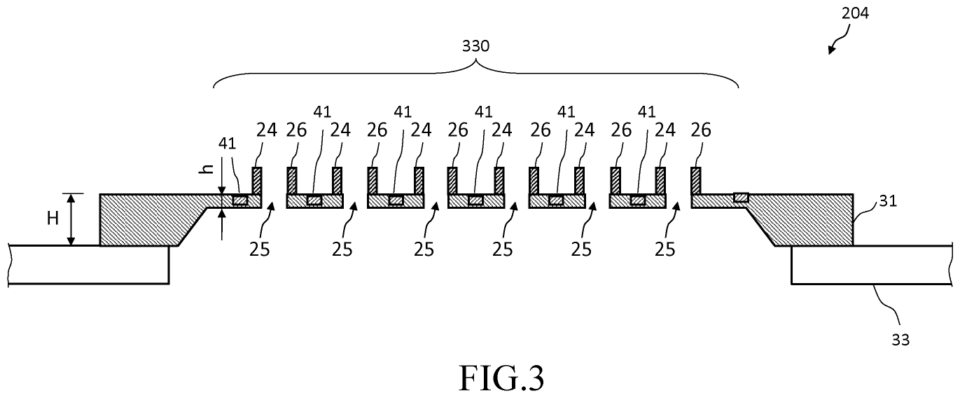

FIG. 3 is a sectional view showing an example of a configuration of a blanking aperture array mechanism according to the first embodiment. In the blanking aperture array mechanism 204, as shown in FIG. 3, a blanking aperture array substrate 31 using a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. In regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam ON condition by passing through the limiting aperture substrate 206. Blanking control is provided by such deflection.

Next, specific examples of operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, one shot of each beam is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the deflectors 208 and 209 in order to irradiate respective beam irradiation positions on the target object 101. For example, when the stage 105 is continuously moving, tracking control is performed by the deflector 208 so that the beam irradiation position may follow the movement of the stage 105. Ideally, the multiple beams 20 irradiating at a time are aligned at the pitch obtained by multiplying the arrangement pitch of a plurality of holes 22 in the shaping aperture array substrate 203 by the desired reduction ratio described above.

In addition to multiple beam writing, for example, in electron beam writing including single beam writing using the VSB method, an alignment mark formed on a target object is detected when the writing target substrate is disposed on the stage. Then, using a detected alignment mark as a reference, alignment of the writing region is carried out. Current alignment marks are formed with a micro line width compared with that of conventional alignment marks.

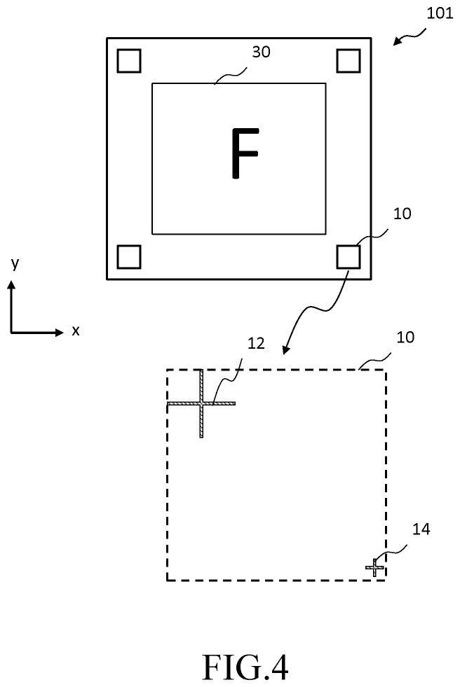

FIG. 4 is a top view showing an example of a configuration of a target object according to the first embodiment. In FIG. 4, on the target object 101, there are set a writing region 30 at the center for writing a desired pattern, and alignment mark regions 10 outside the writing region 30 and, for example, at the four corners of the target object 101 individually. In the example of FIG. 4, four alignment mark regions 10 are set. In each alignment mark region 10, there formed a large mark 12 (an example of an alignment mark and a concave-convex mark) and a small mark 14 (another example of an alignment mark and a concave-convex mark).

FIG. 4 shows the case where the large mark 12 and the small mark 14 are formed at diagonal positions in the alignment mark region 10 of, for example, 11000 μm square. Cross patterns are used as the large mark 12 and the small mark 14, for example. The large mark 12 and the small mark 14 are formed as concave-convex marks of a concave-convex configuration, whose concave (recessed) surface and convex (projected) surface are formed with the same material. A cross pattern serves as a concave (recessed) portion, and the outer portion of the cross pattern serves as a convex (projected) portion. Thereby, concave-convex marks are formed on the target object 101.

The size of the large mark 12 is formed to be large, such as about 4000 μm, and mainly used, as a temporary alignment mark, for searching for the alignment mark region 10 in the wide range region on the surface of the target object 101, for example. The size of the small mark 14 is formed to be small, such as about 400 μm, and used as an alignment mark serving as a position reference. It is also preferable to use the large mark 12 as an alignment mark serving as a position reference, and the small mark 14 as a mark for searching for the alignment mark region 10 in the wide range region on the surface of the target object 101.

For the large mark 12 and the small mark 14, patterns of the same line width are used, for example. Each of the large mark 12 and the small mark 14 is formed by a cross pattern acquired by crossing an x-direction line pattern whose line width at the concave portion is 2 to 200 μm such as 4 to 5 μm, and a y-direction line pattern having the same line width as that of the x-direction line pattern. Detailed configurations are described below.

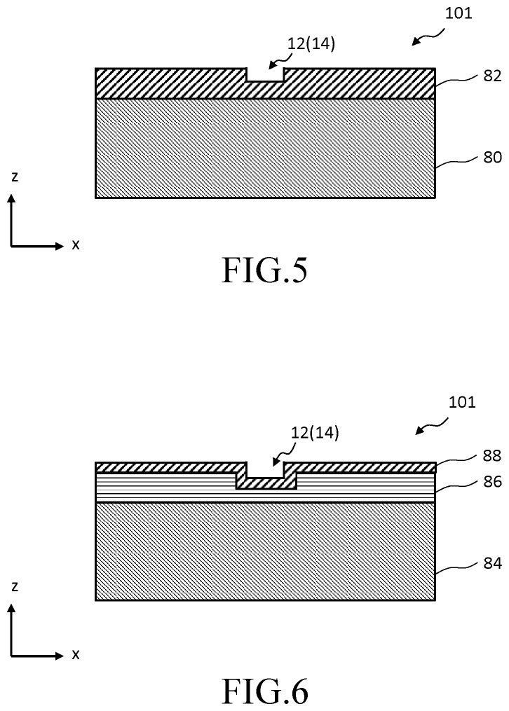

FIG. 5 is a sectional view showing an example of a configuration of an alignment mark according to the first embodiment. FIG. 5 shows the case where an exposure mask is used as the target object 101. As shown in FIG. 5, for example, on a glass substrate 80 of the target object 101, a light shielding film 82 made of chromium (Cr), etc. is formed. Then, a recess is formed in the light shielding film 82. This recessed concave portion is used as the line width of the alignment mark. Therefore, the surface of the concave portion and that of the convex portion form the surface of the same light shielding film 82. Thus, the small mark 14 used as an alignment mark is formed in the concave-convex configuration of the same material. Also, the large mark 12 is similarly formed in the concave-convex configuration of the same material. Then, a resist is applied to the target object 101 (mask) on which these marks are formed, and the target object 101 is transferred into the writing apparatus 100 to perform mark measurement.

FIG. 6 is a sectional view showing another example of a configuration of an alignment mark according to the first embodiment. FIG. 6 shows the case where an EUV exposure mask is used as the target object 101. On a low thermal expansion glass substrate 84 of the target object 101, a multilayer film 86 where, for example, molybdenum (Mo) and silicon (Si) are laminated into multiple layers is formed. Then, a recess is formed in a portion of the multilayer film 86. On the multilayer film 86 including the recess, an absorber film 88 (antireflection film) mainly made of, for example, Cr and tantalum (Ta) is formed. The concave portion of the absorber film 88, which is formed on the concave portion of the multilayer film 86, is used as the line width of the alignment mark. Therefore, the surface of the concave portion and that of the convex portion form the same absorber film 88. Thus, the small mark 14 used as an alignment mark is formed in the concave-convex configuration of the same material. Also, the large mark 12 is similarly formed in the concave-convex configuration of the same material. Then, a resist is applied to the target object 101 (mask) on which these marks are formed. The target object 101 is transferred into the writing apparatus 100 to perform mark measurement.

FIGS. 5 and 6 describe the case where the mark portion is concave, and therefore, processing described below is concave signal processing. However, there may be a case where the mark portion is convex. In that case, the processing is the same as the above, except that an output signal is a convex signal.

Conventionally, an alignment mark on the surface of the target object 101 is detected (searched for) using electron beams, and the position of the alignment mark is measured with the electron beams. However, with respect to a mark of the concave-convex configuration of the same material, if scanning an electron beam over the mark, since difference in electron yields is small, contrast is difficult to obtain. As a result, there is a problem that since the SN ratio is small, the alignment mark on the target object 101 cannot be found easily. To cope with this problem, it is examined to increase the dose (irradiation amount) of an electron beam in order to obtain contrast. However, this method has a problem that because a high dose electron beam is applied to a resist in a wide area, the resist is dispersed (scattered) to contaminate the inside of the writing chamber. Then, according to the first embodiment, using the Z sensor 220, an alignment mark is searched for in a wide range region on the surface of the target object 101 by a laser beam with which no resist is dispersed or a negligible level of resist is dispersed, and the center position of the alignment mark is measured. It is also preferable to measure, with higher accuracy, a mark position according to the need for accuracy. In that case, after specifying the center position of the alignment mark by the laser beam, the center position of the alignment mark is measured by an electron beam to obtain a higher accurate measurement value than that in the case of using a laser beam.

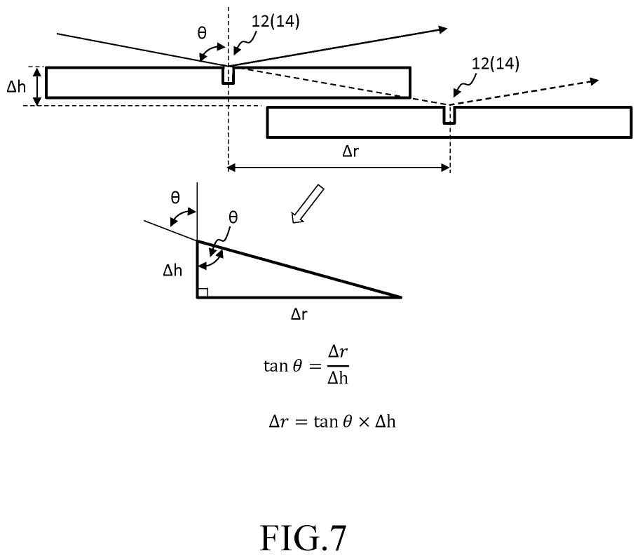

FIG. 7 is an illustration for explaining an error in the case of measuring a mark position by a Z sensor according to the first embodiment. As shown in FIG. 7, the Z sensor 220 applies a laser beam, at an oblique angle, to the surface of the target object 101. In mark measurement by the Z sensor 220, a projected light whose incident angle θ is high such as 80 degrees or more irradiates the surface of the target object 101. For this reason, a height deviation occurs as a lateral deviation error in a measuring result. Therefore, if the height position of the target object 101 deviates, the irradiation position of a laser beam also deviates. For example, when the height position of the surface of the target object deviates by Δh with respect to the incident angle θ of a laser beam of the Z sensor 220, a positional deviation amount Δr can be defined by the following equation (1).

$$Δ r = tan θ \cdot Δ h \qquad ( 1 )$$

FIG. 7 and the equation (1) show the case of defining the direction obtained by projecting the direction of irradiation with a laser beam of the Z sensor 220 on the surface of the target object to be r. Therefore, if the r direction projected in the direction of a laser beam of the Z sensor 220 on the surface of the target object is, for example, the x direction in writing data, it becomes Δr=Δx. Similarly, if the r direction obtained by projecting the direction of a laser beam of the Z sensor 220 on the surface of the target object is, for example, the y direction in writing data, it becomes Δr=Δy. The r direction is not limited to the x direction or the y direction in writing data. For example, the r direction may be the direction of an intermediate angle between the x direction and the y direction in writing data, such as a direction whose phase is shifted by 45 the degrees from the x axis.

Therefore, when measuring the position of the large mark 12 (small mark 14) by the Z sensor 220 as to be described later, if the height position of the surface of the target object deviates by Δh, the actual position of the large mark 12 (small mark 14) deviates in the r direction by the positional deviation amount Δr from the measured position. For example, if the height deviates by 1 μm when the incident angle is 80 degrees, a mark signal is detected at the position deviated in the r direction by Δr=tan 80°×1 [μm]=5.67 μm. Thus, according to the first embodiment, this error is corrected. However, if height measurement for correcting the mark position is performed separately, the writing time becomes long due to the time for the step performed separately. Then, according to the first embodiment, not purposely measuring the height position of the mark in order to correct the mark position, but utilizing data to be use in another step such as a writing step is performed.

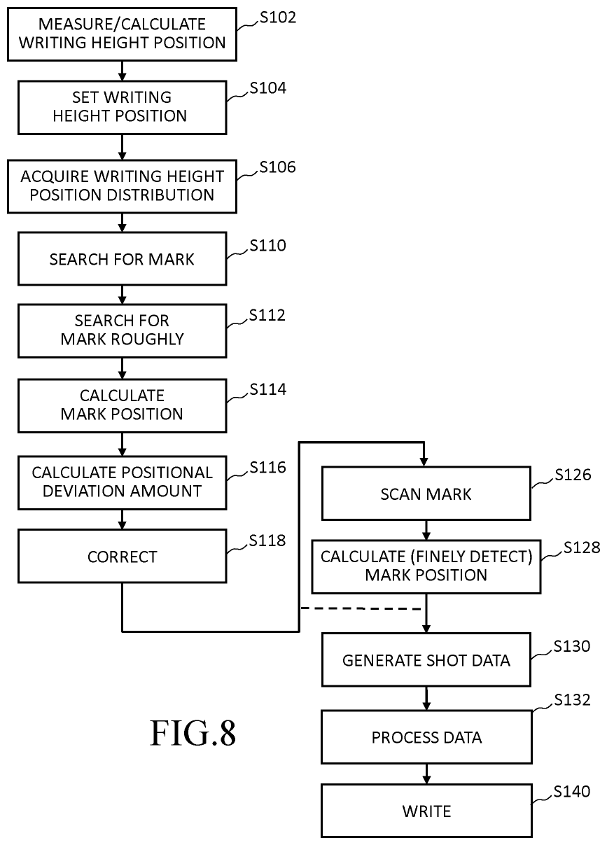

FIG. 8 is a flowchart showing an example of main steps of a writing method according to the first embodiment. In FIG. 8, the writing method of the first embodiment performs a series of steps: a measuring/calculating writing height position step (S102), a setting writing height position step (S104), an acquiring writing height position distribution step (S106), a searching-for mark step (S110), a roughly searching-for mark step (S112), a calculating mark position step (S114), a calculating positional deviation amount step (S116), a correcting step (S118), a scanning mark step (S126), a calculating (finely detecting) mark position step (S128), a generating shot data step (S130), a data processing step (S132), and a writing step (S140). Depending on needed measurement accuracy of a mark position, the scanning mark step (S126) and the calculating (finely detecting) mark position step (S128) may be omitted. In that case, the generating shot data step (S130) is performed after the correcting step (S118).

In the measuring/calculating writing height position step (S102), using the Z sensor 220, height positions are measured at a plurality of preset positions on the target object 101. If, in the step S102, measurement equivalent to the step S106 described later is performed and a height position distribution of the target object surface is simultaneously obtained, the step S106 may be omitted.

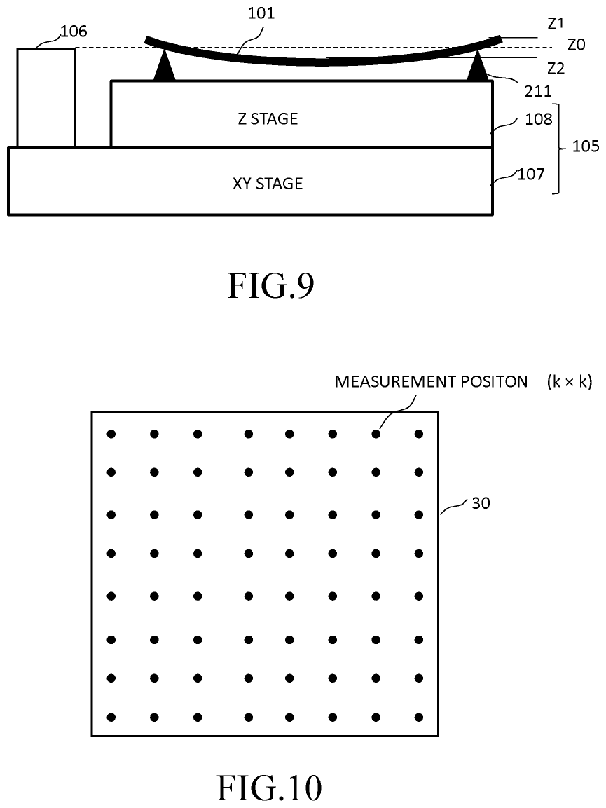

FIG. 9 is an illustration for explaining a stage mechanism and a writing height position according to the first embodiment. In FIG. 9, the stage 105 includes an XY stage 107 and a Z stage 108. In the case of FIG. 9, the Z stage 108 is arranged on the XY stage 107. The mark stand 106 is arranged to be parallel to the Z stage 108, on the XY stage 107. The target object 101 is supported by a plurality of pins 211 on the Z stage 108. For example, it is supported at three points. If the amount of change in the height direction on the surface of the target object 101 does not affect the performance, a value measured in the step S102 is used as it is as the surface height. However, since the outer periphery of the target object 101 is supported by a plurality of pins 211, warping (bending) due to own weight may occur, and height distribution and inclination may be generated as shown in FIG. 9. Then, in S102, a plurality of points on the surface of the target object 101 are measured, and the mask surface height is adjusted so that a writing region may be within a focus range which satisfies writing performances and in which focus adjustment is performable. For example, when the target object surface height distribution is between the highest height Z1 and the lowest height Z2, their midpoint (Z0) is set. Z0 is set at an appropriate position between Z1 and Z2 based on focus function characteristics, pattern arrangement sensitive to a focus, and the like.

In the setting writing height position step (S104), the Z stage 108 is moved to control the height position of the target object 101 so that a calculated height position Z0 may become a reference height position. For example, regarding the surface height position of the mark stand 106 as a reference position, the target object 101 is moved in the z direction by the Z stage 108 so that the calculated height position Z0 may be coincident with the reference height position. By this, the height of the surface of the target object, to be used in the writing step (S140), can be adjusted.

In the acquiring writing height position distribution step (S106), in the state where the height position of the target object above described has been controlled to be a predetermined height position, the height position distribution acquisition unit 52 acquires a height position distribution of the surface of the above-described target object, based on a result obtained by using the sensor above described. In other words, in the state where the height position of the target object 101 has been controlled such that the writing height position Z0, which is set for writing, becomes a reference height position, the height position distribution acquisition unit 52 acquires a height position distribution of the surface of the target object 101, based on a result obtained by using the Z sensor 220. Specifically, it operates as follows:

FIG. 10 is an illustration showing an example of a height measurement position in the surface of a target object according to the first embodiment. In the state where the writing height position Z0 is a reference height position, height positions at a plurality of preset positions on the target object 101 are measured using the Z sensor 220. In the case of FIG. 10, height positions at k×k positions in the writing region 30 of the target object 101, for example, 8×8 positions, are measured.

The Z sensor 220 outputs height position information measured at a plurality of positions, namely, k×k positions, on the surface of the target object 101. The height position distribution acquisition unit 52 calculates a writing height position distribution of the surface of the target object 101 by a predetermined equation, by using the height position information (coordinates of each position, and a height difference from a reference height) at a plurality of positions, namely, k×k positions, on the surface of the target object 101. For example, fitting is performed using a polynomial (e.g., third-order polynomial). Information on the acquired writing height position distribution of the surface of the target object 101 is stored in the storage device 142.

The above example shows the case where, after measuring height positions at k×k positions, a writing height position distribution of the surface of the target object 101 is calculated by a predetermined equation, but it is not limited thereto. For example, it is also preferable that the Z sensor 220 scans each stripe region 32 to measure a height at each position, and a height position distribution is acquired based on the measured height.

In the searching-for mark step (S110), using the Z sensor 220, the large mark 12 is searched for in the wide range region of the target object 101. The position of the alignment mark region 10 on the target object 101 has been set in the design. However, the relative positional relationship between the stage 105 and the target object 101 having been transferred into the writing chamber 103 and placed on the stage 105 is not necessarily in accordance with the design positional relationship perfectly. For example, arrangement deviation of the target object 101 may occur. Accordingly, there may possibly be a case in which the large mark 12 does not exist at the position where the large mark 12 should exist in the design. Then, an actual large mark 12 is searched for based on the design position of the large mark 12. Specifically, the stage 105 is moved to a design position where the large mark 12 should be irradiated with a laser beam from the Z sensor 220. Regarding this position as a reference, the stage 105 is moved, for example, in the −x direction by a predetermined pitch from a position where an irradiation position of a laser beam is sufficiently far, for example, in the −x direction from the reference position. By this method, the actual large mark 12 is searched for, and the height position of the target object 101 is measured at a plurality of measurement positions. Thereby, height positions can be measured at a plurality of measurement positions which are relatively in the x direction on the surface of the target object. Information on measured height positions is output to the control computer 110.

The first height position distribution calculation unit 53 inputs measured height position information, and calculates a height position distribution. Then, the mark region specifying unit 54 searches for a position whose height position is lower than height positions of the surrounding outer positions, and specifies the position as the alignment mark region 10. Details on a height position distribution acquired from the Z sensor 220 will be described later.

In the roughly searching-for mark step (S112), while moving the target object 101 placed on the stage 105, a height position distribution of the surface of the target object 101 is measured, which is obtained by scanning a laser beam, using the Z sensor 220, such that the laser beam intersects the small mark 14 (or large mark 12) (concave-convex mark) in the specified alignment mark region 10. If the alignment mark region 10 is located at each of four corners of the target object 101, the roughly searching-for mark step (S112) for the small mark 14 (or large mark 12) (concave-convex mark) is performed in each of the specified alignment mark regions 10 at the four corners.

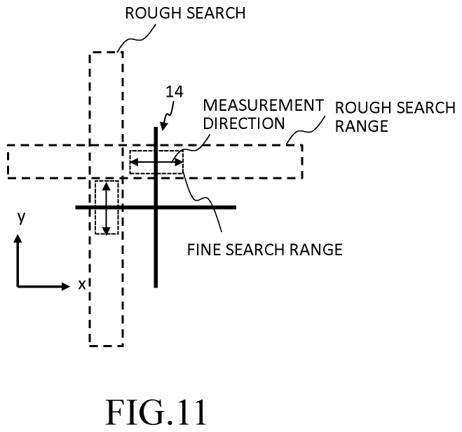

FIG. 11 is an illustration explaining a method of roughly searching for a mark according to the first embodiment. As shown in FIG. 11, the small mark 14 has been formed by cruciformly intersecting the line pattern in the x direction and the line pattern in the y direction. Then, the position of the line pattern of the small mark 14 is measured in FIG. 11. Defining the direction perpendicular to the direction of the line pattern as a measurement direction, scanning is performed in the measurement direction. For example, the distance twice the beam diameter of the laser beam is scanned. FIG. 11 shows the case where the line pattern in the y direction is scanned in the x direction, and the line pattern in the x direction is scanned in the y direction. Specifically, by moving the stage 105, the irradiation position, on the surface of the target object 101, of the laser beam from the Z sensor 220 is serially moved to a plurality of measurement positions. If there are many noise signals dependent on a location, etc., noise components are averaged or cancelled out by performing calculation repeatedly to average the noise components at a plurality of locations which are in a non-measurement direction perpendicular to the measurement direction. For example, when measuring the line pattern in the y direction described above, after scanning and measuring in the x direction, it moves stepwise in the y direction, and then, performs scanning and measurement in the x direction, which is performed repeatedly. In the roughly searching-for mark step (S112), when scanning in the x and y directions, as shown in FIG. 11, it is preferable to perform scanning in a range larger than the size of the target mark (here, for example, the small mark 14).

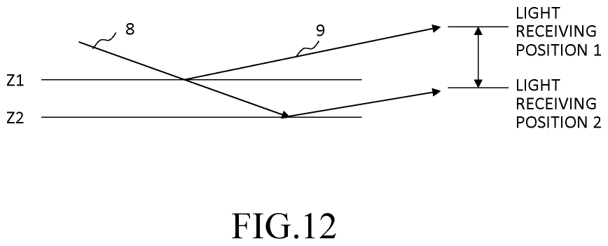

FIG. 12 is an illustration for explaining a measurement principle of a Z sensor according to the first embodiment. In FIG. 12, the light receiving position 1 is the position of the center of gravity of a reflected light 9 which is a reflected light of a laser beam 8 reflected at the height Z1 and is received by a photoreceiver. The light receiving position 2 is the position of the center of gravity of a reflected light 9 which is a reflected light of the laser beam 8 reflected at the height Z2 and is received by a photoreceiver. Thus, the light receiving positions are different (changed). The height position on the surface of the target object 101 can be calculated by multiplying the light receiving position by a height conversion coefficient.

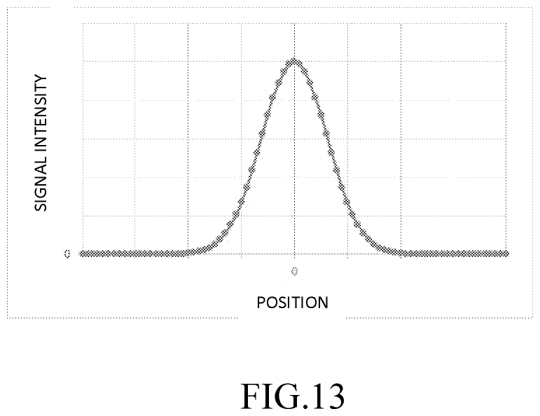

FIG. 13 is an illustration showing an example of an intensity distribution of a laser beam used by a Z sensor according to the first embodiment. As shown in FIG. 13, the laser beam used by the Z sensor 220 of the first embodiment has a light intensity distribution of normal distribution. That is, the intensity of the laser beam becomes large as it goes close to the center of the beam, and the intensity becomes small as it radially goes outward. Preferably, for example, a visible light is used as the laser beam.

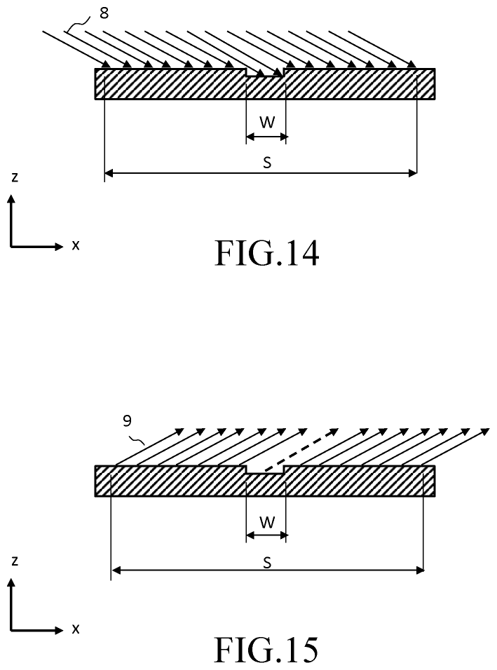

FIG. 14 is a sectional view showing an example of the state of an irradiation light in the case of scanning an alignment mark by a Z sensor according to the first embodiment.

FIG. 15 is a sectional view showing an example of the state of a reflected light in the case of scanning an alignment mark by a Z sensor according to the first embodiment.

With miniaturization of the line width of the large mark 12 and the small mark 14, the size larger than the width size (line width size) of the large mark 12 (concave-convex mark) and the small mark 14 (concave-convex mark) is used as the diameter size of the laser beam 8 used by the Z sensor 220. The surface of the target object 101 is irradiated with a laser beam having a diameter of, for example, 10 to 300 μm. The surface of the target object 101 is irradiated with a laser beam having a diameter of 200 μm, for example. The irradiator 222 of the Z sensor 220 applies the laser beam 8 in oblique incidence on the surface of the target object 101. Therefore, as shown in FIG. 14, the large region having the width S including the small mark 14 (or large mark 12) having the line width W is irradiated with the laser beam 8 at a time. Then, the photoreceiver 224 receives the reflected light 9 from the target object 101 due to irradiation of the laser beam 8. At this time, simultaneously, as shown in FIG. 15, the photoreceiver 224 receives the reflected light 9 from the large region having the width S including the small mark 14 (or large mark 12) having the line width W. As shown in FIG. 15, the reflected light 9 partially includes a light (dotted line) with information on the height of the bottom surface of the concave portion of the small mark 14 (or large mark 12) (concave-convex mark). Then, the photoreceiver 224 outputs information on the height of the surface of the target object 101.

In the calculating mark position step (S114), the second height position distribution calculation unit 56 inputs information on the measured height position, and calculates a height position distribution. As shown in FIG. 11, the height position distribution of the surface of the target object 101 can be obtained by performing scanning such that the laser beam 8 intersects the small mark 14 (or large mark 12) (concave-convex mark). Positions of the line pattern are measured at the upper, lower, right, and left positions of the small mark 14 (or large mark 12) in terms of the directional relationship shown in FIG. 11 in the roughly searching-for mark step (S112). In this process, since the measurement is repeated multi-stepwise while shifting the position in the extending direction (non-measurement direction) of the line pattern, information on multi-step height positions is output from the photoreceiver 224. Then, the height position distribution calculation unit 50 averages the measuring results, measured at multiple steps, in the non-measurement direction. Thereby, the influence of a difference between mark positions and that of a noise at the measurement time can be reduced.

If the small mark 14 (or large mark 12) exists at each of the four corners of the target object 101, a height position distribution is calculated similarly for each small mark 14 (or large mark 12) (concave-convex mark).

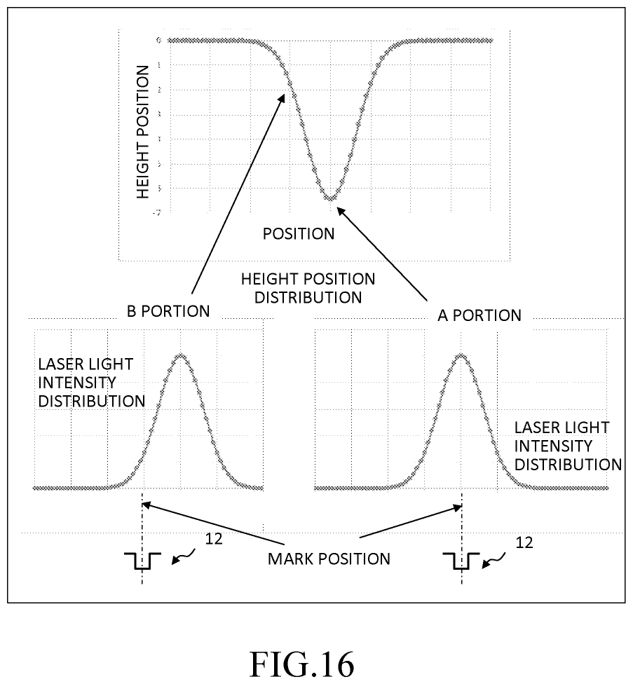

FIG. 16 is an illustration showing an example of a height position distribution of a concave-convex mark according to the first embodiment. In FIG. 16, the ordinate axis represents a height position and the abscissa axis represents a position (for example, a position in the x direction) on a target object. In the first embodiment, the laser beam 8 used by the Z sensor 220 has a light intensity distribution of normal distribution. If the laser beam 8 has a light intensity distribution, the reflected light 9 also has a light intensity distribution depending on the light intensity of the laser beam 8 being the original. The height position can be calculated by multiplying the light receiving position of the position of the center of gravity of the received reflected light 9 by a height conversion coefficient.

The position of the center of gravity of the reflected light 9 is affected by a light intensity of each light receiving position on the light receiving surface of the photoreceiver 224. Therefore, change of the position of the center of gravity can be made larger in the case of obtaining height information on the concave bottom by a portion with a high light intensity compared with the case of obtaining it by a portion with a low light intensity. Consequently, as shown in FIG. 16, when the small mark 14 (or large mark 12) having the line width W is located within the beam diameter of the laser beam 8, the height position changes depending on which position of the light intensity distribution positions irradiates the small mark 14 (or large mark 12) having the line width W. As shown in FIG. 16, the A portion of the height position shows the case where the small mark 14 (or large mark 12) is irradiated by the peak position (the maximum value of light intensity) of the light intensity of the laser beam 8. The B portion of the height position shows the case where the small mark 14 (or large mark 12) is irradiated by the position of, for example, around 20% light intensity of the light intensity peak position (the maximum value of light intensity) of the laser beam 8. As shown in FIG. 16, the higher the light intensity of a position to irradiate the small mark 14 (or large mark 12), the larger the change of the height position of the concave compared with the height position of the convex. If the light intensity distribution of the laser beam 8 is normal distribution, when the small mark 14 (or large mark 12) is irradiated by the peak position of the normal distribution, the height position of the concave is output as the lowest height position from the photoreceiver 224. Therefore, as shown in FIG. 16, the height position distribution of the surface of the target object 101 includes a portion which continuously changes in the same direction in a range larger than the width size of the small mark 14 (or large mark 12) (concave-convex mark), and which is generated due to a relative position relation between the light intensity distribution and the small mark 14 (or large mark 12) (concave-convex mark). At the left of the peak position of the height position distribution, it changes such that the height position continuously becomes lower toward the peak position from the height position of the convex. In contrast, at the right of the peak position of the height position distribution, it changes such that the height position continuously becomes higher toward the height position of the convex from the peak position.

According to the first embodiment, not only the case where the peak position indicates the upward maximum height position of a convex signal but also the case of indicating the downward minimum position of a concave signal is included. The peak position described herein indicates the downward minimum height position.

The height position distribution described above is calculated at each of the upper, lower, right, and left positions of the small mark 14 (or large mark 12).

Next, in the state where the height position of the target object has been controlled to be a predetermined height position, the first mark position calculation unit 58 calculates positions of a plurality of marks by using change of a signal for a mark of the plurality of marks due to a state of a surface of the target object 101, obtained by the Z sensor 220 by scanning a laser beam over the plurality of marks such that the laser beam intersects the plurality of marks. In other words, in the state where the height position of the target object 101 has been controlled such that the writing height position Z0, which is set for writing, becomes a reference height position, the first mark position calculation unit 58 calculates, for each mark, the position of the mark concerned by using a height position distribution of the surface of the target object 101 for each mark, which is obtained by the Z sensor 220 by scanning a laser beam over a plurality of marks such that the laser beam intersects the plurality of marks. Specifically, it operates as follows:

The first mark position calculation unit 58 inputs a height position distribution with respect to each position of the upper, lower, right, and left of the small mark 14 (or large mark 12) (concave-convex mark).

The first mark position calculation unit 58 calculates, as a mark position, a peak position of a normal distribution acquired by approximating a height position distribution of the surface of the target object 101 by using a density function of normal distribution (hereinafter referred to as a normal distribution function).

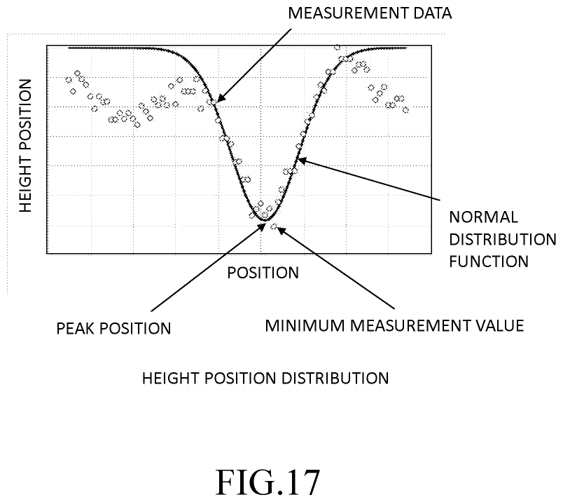

FIG. 17 is an illustration showing an example of a height position distribution according to the first embodiment. In FIG. 17, the ordinate axis represents a height position and the abscissa axis represents a position. In FIG. 17, measurement data on a plurality of measurement positions in a scanning direction are plotted. By approximating the measurement data of the plurality of measurement positions in the scanning direction by a normal distribution function, the peak position of an approximate line is calculated as a mark position.

Alternatively, it is also preferable that the first mark position calculation unit 58 calculates the position of the center of gravity of a height position distribution of the surface of the target object 101, and obtains the position of the center of gravity as a mark position. The position of the center of gravity, g, can be calculated by the following equation (2) using a coordinate mi and a height position hi of measurement data. i indicates an index.

$$g = Σ ( m i \cdot hi ) / Σ hi \qquad ( 2 )$$

Alternatively, it is also preferable that the first mark position calculation unit 58 calculates, as a mark position, the position of the minimum height measurement value of a height position distribution of the surface of the target object 101. The minimum height measurement value in measurement data on a plurality of measurement positions shown in FIG. 17 is calculated as a mark position.

When the mark portion is convex, since the direction of a signal becomes convex, it is also preferable to calculate the position of the maximum height measurement value as a position of a mark.

The first mark position calculation unit 58 can obtain the x position (x coordinate) of the center of a mark by calculating an average value between the x position measured at the upper position of the small mark 14 (or large mark 12) and the x position measured at the lower position of the small mark 14 (or large mark 12). Also, the y position (y coordinate) of the center of a mark can be obtained by calculating an average value between the y position measured at the right position of the small mark 14 (or large mark 12) and the y position measured at the left position of the small mark 14 (or large mark 12).

As a signal change due to the state of the surface of the target object 101 of a mark acquired by the Z sensor 220 used when calculating positions of a plurality of marks, there may be a change of a light reception amount received by the photoreceiver 224 in addition to a change of a height position shown in the above height position distribution.

As described above, when an error exits in the height position of the surface of the target object 101, a positional deviation corresponding to the height error has occurred in the calculated mark position. Then, correction is performed as described below.

In the calculating positional deviation amount step (S116), the positional deviation amount calculation unit 60 calculates, for each mark, a positional deviation amount Δr from a calculated position of a mark concerned, by using an incident angle θ of a laser beam, and surface height positions of the target object 101 at a plurality of mark positions acquired from an obtained writing height position distribution of the surface of the target object 101. The writing height position distribution stored in the storage device 142 can be calculated by the predetermined equation as described above. Therefore, referring to the writing height position distribution, the positional deviation amount calculation unit 60 calculates, for each mark, a positional deviation amount by using the height position of the mark position concerned obtained by the predetermined equation. A positional deviation amount at the mark position concerned can be calculated, for each mark, by substituting a height error Δh at the mark position concerned from the reference height position, and an incident angle θ into the equation (1).

In the correcting step (S118), the correction unit 62 corrects, for a plurality of marks, the calculated position of the mark concerned by using a positional deviation amount concerned in a plurality of calculated positional deviation amounts. In other words, the correction unit 62 corrects, for each mark, the calculated position of the mark concerned by using a calculated positional deviation amount Δr. Specifically, the position obtained by adding a vector Δr to the calculated coordinates (x0, y0) of the position of the mark concerned becomes an actual mark position. For example, when the r direction is coincident with the x direction, the actual mark position is coordinates (x0+Δr, y0).

By the process described above, a positional deviation of a mark position resulting from an error of the height position of the target object 101 can be corrected. Information on a corrected position of each mark is output to the storage device 142 and the like, and stored therein.

Next, the center position of an alignment mark is measured, with high accuracy, using an electron beam. Specifically, using information on each mark position whose positional deviation has been corrected, in the state in which the stage 105 has been moved to a position where the small mark 14 (concave-convex mark) can be irradiated with an electron beam, the position of the small mark 14 (concave-convex mark) is measured by scanning an electron beam over the small mark 14 (concave-convex mark).

In the scanning mark step (S126), first, using the information on each mark position whose positional deviation has been corrected, for each mark, the stage 105 is moved to a position where the small mark 14 (concave-convex mark) can be irradiated with an electron beam. Then, in the state in which the stage 105 has been moved to the position where the small mark 14 (concave-convex mark) can be irradiated with an electron beam, scanning over the small mark 14 (concave-s mark) is performed by deflecting an electron beam by the deflector 209. For example, as described referring to FIG. 11, the upper, lower, right, and left positions of the small mark 14 are scanned. However, here, it is sufficient to perform scanning in the range of 20 to 30 μm in the measurement direction, for example. Thus, compared with a conventional case, the range scanned by an electron beam can be substantially reduced. As an electron beam used for this scanning, it is preferable to use one beam selected from the multiple beams 20, or use several beams including the selected beam and beams adjacent to the selected beam. As the processing of beam selection, it is set such that selected beam (or beams) is made to be ON and the other beams (beam array) are made to be OFF by the blanking aperture mechanism 204.

Secondary electrons emitted from the target object 101 when the small mark 14 (concave-convex mark) was scanned are detected by the detector 226. Detected data is converted into digital data from analog data by the detector 226 and is amplified to be output from the detector 226 to the control computer 110.

In the calculating (finely detecting) mark position step (S128), the second mark position calculation unit 68 calculates the center position of the small mark 14 (concave-convex mark) by using secondary electron image data, obtained at each of the upper, lower, right, and left positions of the small mark 14, generated based on a second electron in the scanning mark step (S126). For example, both the edge positions which configure each of a vertical line width and a lateral line width of the small mark 14 in a secondary electron image are measured. Then, an average value of the center positions of vertical line widths and an average value of the center positions of lateral line widths are obtained as x and y coordinates of the small mark 14.

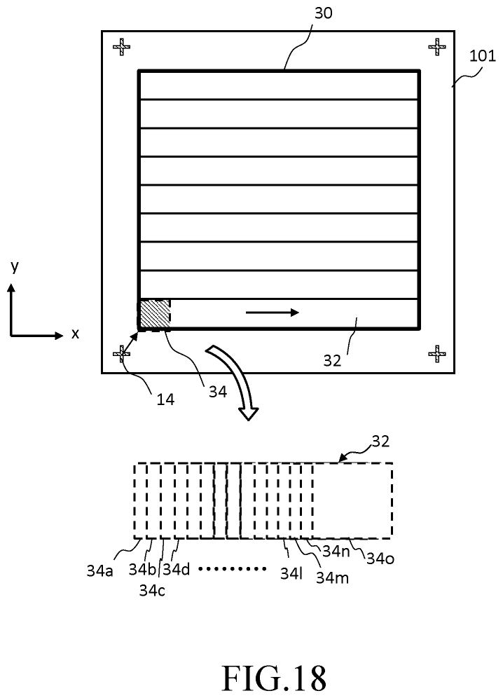

FIG. 18 is a conceptual diagram showing an example of a writing operation according to the first embodiment. As shown in FIG. 18, the position of the writing region 30 (bold line) of the target object 101 is defined based on an acquired position of the small mark 14 serving as an alignment mark, for example. The writing region 30 (bold line) is virtually divided into a plurality of stripe regions 32 by a predetermined width in the y direction, for example. In the case of FIG. 18, the writing region 30 of the target object 101 is divided into the plurality of stripe regions 32 by the width size being substantially the same as the design size of an irradiation region 34 (writing field) that can be irradiated with one irradiation of the multiple beams 20. The x-direction design size of the irradiation region 34 of the multiple beams 20 can be defined by (the number of x-direction beams)×(x-direction beam pitch). The y-direction size of the rectangular irradiation region 34 can be defined by (the number of y-direction beams)×(y-direction beam pitch).

First, the stage 105 is moved to make an adjustment such that the irradiation region 34 of the multiple beams 20 is located at the left end, or at a position further left than the left end, of the first stripe region 32, and then writing of the first stripe region 32 is performed. When writing the first stripe region 32, the stage 105 is moved, for example, in the −x direction, so that the writing may proceed relatively in the x direction. The stage 105 is moved continuously at a constant speed, for example. After writing the first stripe region 32, the stage position is moved in the −y direction by the width of the stripe region 32.

Next, an adjustment is made so that the irradiation region 34 of the multiple beams 20 can be located at the left end, or at a position further left than the left end, of the second stripe region 32. Then, writing of the second stripe region 32 is performed by moving the stage 105, for example, in the −x direction to proceed the writing relatively in the x direction.

FIG. 18 shows the case where respective stripe regions 32 are written in the same direction, but, it is not limited thereto. For example, with respect to the stripe region 32 to be written following the stripe region 32 having been written in the x direction, it may be written in the −x direction by moving the stage 105 in the x direction, for example. Thus, due to performing writing while alternately changing the writing direction, the stage moving time can be reduced, which results in reducing the writing time. Owing to one shot of multiple beams 20 having been formed by individually passing through the holes 22 in the shaping aperture array substrate 203, a plurality of shot patterns up to the number of the holes 22 are maximally formed at a time.

Although FIG. 18 shows the case where the stage moving for writing each stripe region is performed once for each writing, it is not limited thereto. It is also preferable to perform multiple writing such that the stage moves on the same position a plurality of times. In that case, it is preferable to perform multiple writing while shifting the position in the y direction by 1/n of the width of the stripe region.

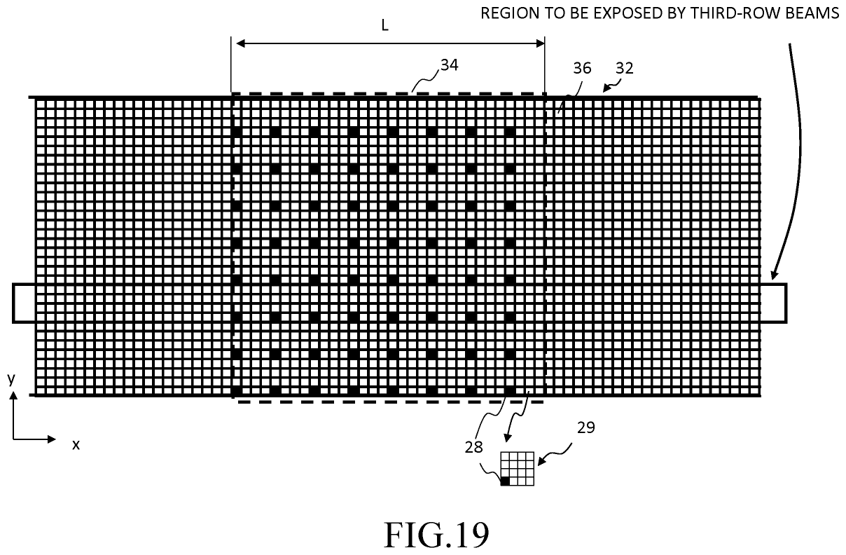

FIG. 19 is an illustration showing an example of an irradiation region of multiple beams and a pixel to be written (writing target pixel) according to the first embodiment. In FIG. 19, the stripe region 32 is divided into a plurality of mesh regions by the beam size of each of the multiple beams 20, for example. Each mesh region serves as a writing pixel 36 (unit irradiation region, irradiation position, or writing position). The size of the writing pixel 36 is not limited to the beam size, and may be any size regardless of beam size. For example, it may be 1/n (n being an integer of 1 or more) of the beam size. FIG. 19 shows the case where the writing region of the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the rectangular, including square, irradiation region 34 can be defined by (the number of x-direction beams)×(beam pitch in the x direction). The y-direction size of the rectangular irradiation region 34 can be defined by (the number of y-direction beams)×(beam pitch in the y direction). FIG. 19 shows the case of multiple beams of 512×512 (rows×columns) having been simplified to 8×8 (rows×columns). In the irradiation region 34, there are shown a plurality of pixels 28 (beam writing positions) which can be irradiated with one shot of the multiple beams 20. The pitch between adjacent pixels 28 is the beam pitch of the multiple beams. A sub irradiation region 29 (pitch cell) is configured by a rectangular, including square, region surrounded by the size of beam pitches in the x and y directions. In the example of FIG. 19, each sub irradiation region 29 is composed of 4×4 pixels, for example.

In the generating shot data step (S130), first, the shot data generation unit 70 generates shot data for each pixel 36. Specifically, it operates as follows: First, the shot data generation unit 70 reads writing data from the storage device 140, and calculates, for each pixel 36, a pattern area density ρ′ in the pixel 36 concerned. This processing is performed for each stripe region 32, for example.

Next, the shot data generation unit 70, first, virtually divides the writing region (e.g., in this case, stripe region 32) into a plurality of proximity mesh regions (mesh regions for proximity effect correction calculation) by a predetermined size. The size of the proximity mesh region is preferably about 1/10 of the influence range of the proximity effect, such as about 1 μm. The shot data generation unit 70 reads writing data from the storage device 140, and calculates, for each proximity mesh region, a pattern area density ρ″ of a pattern arranged in the proximity mesh region concerned.

Next, the shot data generation unit 70 calculates, for each proximity mesh region, a proximity effect correction irradiation coefficient Dp(x) (correction dose) for correcting a proximity effect. An unknown proximity effect correction irradiation coefficient Dp(x) can be defined by a threshold value model for proximity effect correction, which is the same as the one used in a conventional method, where a backscatter coefficient η, a dose threshold value Dth of a threshold value model, a pattern area density ρ″, and a distribution function g(x) are used.

Next, the shot data generation unit 70 calculates, for each pixel 36, an incident dose D(x) (amount of dose) with which the pixel 36 concerned is irradiated. The incident dose D(x) can be calculated, for example, by multiplying a base dose Dbase by a proximity effect correction irradiation coefficient Dp and a pattern area density ρ′. The base dose Dbase can be defined by Dth/(½+η), for example. Thereby, it is possible to obtain an incident dose D(x) for each pixel 36, for which a proximity effect has been corrected, based on layout of a plurality of figure patterns defined by the writing data.

Next, the shot data generation unit 70 calculates an irradiation time for each pixel 36. The irradiation time for each pixel 36 can be obtained by diving an incident dose D(x) of the pixel concerned by a current density J.

In the data processing step (S132), the data processing unit 72 rearranges obtained irradiation time data for each pixel 36 in order of shot, and stores it in the storage device 142. The transmission processing unit 74 transmits, in order of shot, the irradiation time data to the deflection control circuit 130.

In the writing step (S140), under the control of the control unit 76, in the state where the height position of the target object 101 has been controlled such that the writing height position Z0, which is set for writing, becomes a reference height position, the writing mechanism 150 writes a pattern on the target object 101 with the multiple beams 20 (electron beam), based on information on the corrected position of each mark. As described above, while moving the stage 105, the writing mechanism 150 writes a pattern on the target object 101 placed on the stage 105 with the multiple beams 20. In this process, if there is unevenness in the distribution of the height on the surface of the target object, the focus position by the objective lens 207 deviates. Then, for example, the electrostatic lens 212 refers to a writing height position distribution on the surface of the target object stored in the storage device 142, and dynamically corrects (performs dynamic focusing) the deviation of the focus position of the multiple beams 20 corresponding to each height position. Alternatively, as long as response performance is satisfactory (as long as no delay occurs), it is also preferable to perform controlling to focus of the position of multiple beams 20 corresponding to the height position, referring to the height position distribution of the surface of the target object by the objective lens 207.

In the multiple beam writing, in parallel with performing the writing processing, the control computer 110 generates shot data for a region in which writing processing is to be performed later. For example, while performing writing to the k-th stripe region 32, shot data for the (k+2)th stripe region 32 is generated in parallel. Repeating such an operation, all the stripe regions 32 are written.

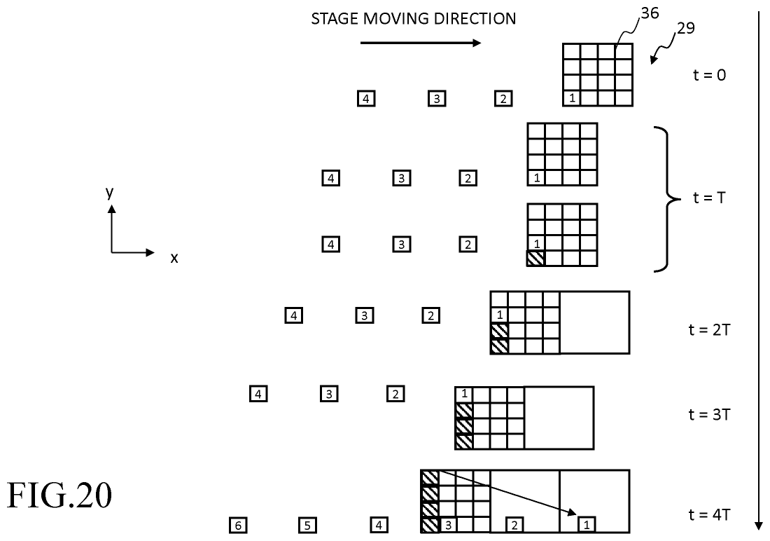

FIG. 20 is an illustration explaining an example of a multi-beam writing operation according to the first embodiment. FIG. 20 shows the case where the inside of each sub-irradiation region 29, which includes the beam irradiation position of one of the multiple beams 20 and is surrounded with the beam pitch (pitch between beams), is written with four different beams. The example of FIG. 20 shows a writing operation where, during a ¼ region namely the region of 1/(the number of beams used for irradiation) in each sub-irradiation region 29 being written, the stage 105 continuously moves at the speed at which it moves the distance of two beam pitches. FIG. 20 shows the case where each sub-irradiation region 29 is composed of 4×4 pixels, for example.

In the writing operation shown in FIG. 20, for example, while the stage 105 moves the distance of two beam pitches in the x direction, respective four pixels 36 in the same sub-irradiation region 29 are written (exposed) by applying a shot cycle T of four shots of the multiple beams 20 with shifting the irradiation position (pixel 36) in order by the deflector 209. In order that the relative position between the irradiation region 34 and the target object 101 may not be shifted by the movement of the stage 105 while these four pixels 36 are written (exposed), the irradiation region 34 is made to follow the movement of the stage 105 by collective deflection of all of the multiple beams 20 by the deflector 208. In other words, a tracking control is performed. After one tracking cycle is completed, tracking is reset to return to the previous (last) tracking start position. Since writing of the pixels in the first column from the left of each sub-irradiation region 29 has been completed, in the next tracking cycle after resetting the tracking, first, the deflector 209 provides deflection such that the writing position of a beam which is different from that used for the first pixel column is adjusted (shifted) to write the second pixel column from the left still not having been written in each sub-irradiation region 29, for example. By repeating this operation during performing writing to the stripe region 32, as shown in the lower part of FIG. 18, the position of the irradiation region 34 (34a to 34o) of the multiple beams 20 is sequentially moved (shifted) to perform writing.

As described above, according to the first embodiment, it is possible to highly accurately measure positions of a plurality of marks, whose concave surface and convex surface are made of the same material, formed on the target object 101. Furthermore, in the case of correcting a mark position, it is possible to perform correction not by purposely measuring the height position of each mark but by using information acquired in the operation for writing (acquisition of a writing height position distribution). Eventually, an increase in writing time can be prevented.

### Second Embodiment

In the first embodiment, correction is performed using a height of a mark position obtained from a writing height position distribution, but, it is not limited thereto. A second embodiment will describe a configuration where correction is performed using a height of a mark position obtained from a distribution of height positions, around a mark position, measured in the roughly searching-for mark step (S112).

The configuration of the writing apparatus 100 according to the second embodiment may be the same as that of FIG. 1. Furthermore, the flowchart showing an example of main steps of a writing method according to the second embodiment may be the same as that of FIG. 8. Similarly to the first embodiment, in the second embodiment, depending on needed measurement accuracy of a mark position, the scanning mark step (S126) and the calculating (finely detecting) mark position step (S128) may be omitted. In that case, the generating shot data step (S130) is performed after the correcting step (S118).

The contents of the second embodiment are the same as those of the first embodiment except for what is particularly described below.

The contents of each of the measuring/calculating writing height position step (S102), the setting writing height position step (S104), the acquiring writing height position distribution step (S106), the searching-for mark step (S110), the roughly searching-for mark step (S112), and the calculating mark position step (S114) are the same as those of the first embodiment.

In the calculating positional deviation amount step (S116), the positional deviation amount calculation unit 60 calculates, for each mark, a positional deviation amount Δr deviated from a calculated position of a mark concerned, by using an incident angle θ of a laser beam, and surface height positions of the target object 101 in the vicinity of at least a plurality of mark positions obtained when scanning a plurality of marks in the roughly searching-for mark step (S112).

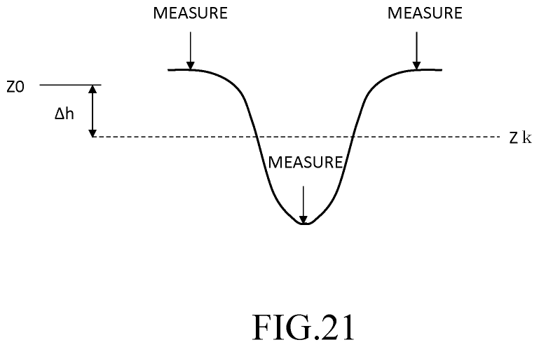

FIG. 21 is an illustration showing an example of surface height positions of a target object in the vicinity of a mark position including the mark position itself according to the second embodiment. In the example of FIG. 21, the position of the downward peak indicates a mark position. In that case, the positional deviation amount calculation unit 60 calculates, for each mark, a positional deviation amount by using a plurality of height position information on a plurality of positions, including the mark position concerned, obtained in the range of scanning the mark concerned. In the case of FIG. 21, for example, an average value between the height of the downward peak position, which is a mark position, and heights at a plurality of positions (for example, two positions) in the vicinity outside the concave portion, for example, is defined as a height position Zk. Alternatively, for example, an average value of heights of a plurality of positions, including the height of the downward peak position which is a mark position, the height of a position in the vicinity outside the concave portion, and the height of a position in the concave portion other than the peak, is defined as a height position Zk. Then, using a difference Δh from the writing height position Z0, a positional deviation amount Δr is calculated.

Alternatively, it is also preferable that the positional deviation amount calculation unit 60 calculates, for each mark, a positional deviation amount by using a plurality of height position information on a plurality of positions, excluding the mark position concerned, obtained in the range of scanning the mark concerned. Without including the height of the downward peak position, which is a mark position, for example, an average of heights at a plurality of positions (for example, two positions) in the vicinity outside the concave portion is defined as a height position Zk. Then, using a difference Δh from the writing height position Z0, a positional deviation amount Δr is calculated.

The contents of each step after the correcting step (S118) are the same as those of the first embodiment.

As described above, according to the second embodiment, since the surface height Zk at a mark position on the target object is calculated by using a height position distribution acquired when roughly searching for the mark position, the processing time and effort for purposely measuring, for performing correction, the surface height Zk at the mark position on the target object can be omitted. Thus, when correcting a mark position, correction can be performed using information obtained in the operation (mark rough search) for writing. Eventually, an increase in writing time can be prevented.

### Third Embodiment

In each of the Embodiments described above, a positional deviation amount Δr is calculated using a height of a mark position measured or calculated in the state of having been controlled to be a writing height position Z0, but, the method of acquiring a mark position with great accuracy is not limited thereto. A third embodiment will describe a configuration in which a mark position is calculated in the state where a positional deviation amount is in an allowable range without correction, or in the state where a positional deviation amount is small even though correction is performed.

The configuration of the writing apparatus 100 according to the third embodiment may be the same as that of FIG. 1. The contents of the third embodiment may be the same as those of the first or second embodiment except for what is particularly described below.

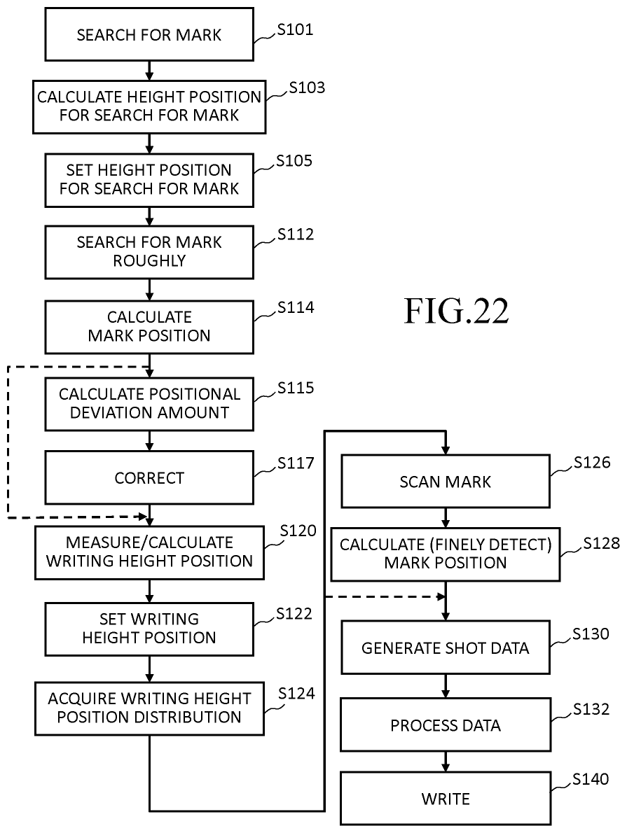

FIG. 22 is a flowchart showing an example of main steps of a writing method according to the third embodiment. In FIG. 22, the writing method of the third embodiment performs a series of steps: a searching-for mark step (S101), a calculating height position for searching-for mark step (S103), a setting height position for searching-for mark step (S105), the roughly searching-for mark step (S112), the calculating mark position step (S114), a calculating positional deviation amount step (S115), a correcting step (S117), a measuring/calculating writing height position step (S120), a setting writing height position step (S122), an acquiring writing height position distribution step (S124), the scanning mark step (S126), the calculating (finely detecting) mark position step (S128), the generating shot data step (S130), the data processing step (S132), and the writing step (S140).

Similarly to the first and second embodiments, depending on needed measurement accuracy of a mark position, the scanning mark step (S126) and the calculating (finely detecting) mark position step (S128) may be omitted.

Furthermore, according to the third embodiment, depending on positional deviation accuracy of a mark position, the calculating positional deviation amount step (S115) and the correcting step (S117) may be omitted.

In the searching-for mark step (S101), in the state where the target object 101 has been transferred on the stage 105, the large mark 12 is searched for, using the Z sensor 220, in the wide range region on the target object 101.

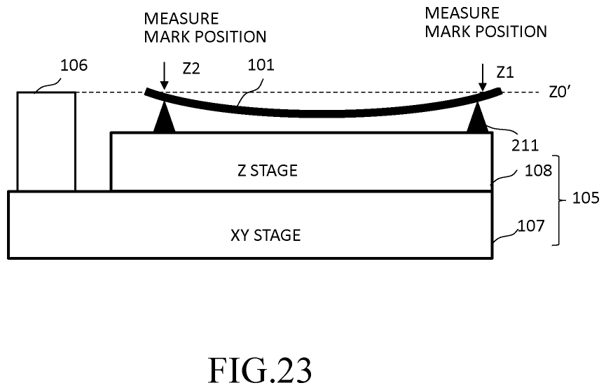

FIG. 23 is an illustration for explaining a stage mechanism, and a height position for searching for a mark according to the third embodiment. In FIG. 23, the stage 105 includes the XY stage 107 and the Z stage 108. In the case of FIG. 23, the Z stage 108 is arranged on the XY stage 107. The mark stand 106 is arranged to be parallel to the Z stage 108, on the XY stage 107. The target object 101 is supported by a plurality of pins 211 on the Z stage 108. For example, it is supported at three points. Since the outer periphery of the target object 101 is supported by a plurality of pins 211, warping (bending) due to own weight occurs as shown in FIG. 23. Here, using the Z sensor 220, the actual large mark 12 is searched for based on the position of the design large mark 12. Heights of an outer peripheral portion and the central part of the target object 101 are measured. Specifically, in the state where the target object 101 has been transferred on the stage 105, the XY stage 107 is moved to put the irradiation position of the laser beam of the Z sensor 220 on the outer periphery of the target object 101. Then, the height of an outer peripheral portion of the target object 101 is measured in that state. As the outer peripheral portion of the target object 101, for example, four peripheral portions of the target object 101 are measured one by one. Similarly, the XY stage 107 is moved to put the irradiation position of the laser beam of the Z sensor 220 on the center position of the target object 101. Then, the height of the center position of the target object 101 is measured in that state. The method of searching is the same as that of the searching-for mark step (S110) of the first or second embodiment. Information on measured height position is output to the control computer 110.

The first height position distribution calculation unit 53 inputs measured height position information, and calculates a height position distribution. Then, the mark region specifying unit 54 searches for a position whose height position is lower than height positions of the surrounding outer positions, and specifies the position as the alignment mark region 10.

In the calculating height position for searching-for mark step (S103), the height position calculation unit 50 calculates a height position (first height position) for searching for a mark, by using height position information, obtained by the Z sensor 220, on each position of positions where it is assumed that a plurality of marks exist. When alignment marks (the large mark 12 or the small mark 14) are arranged at four corners on the surface of the target object 101, an average of a plurality of height positions measured, by the Z sensor 220, at the mark positions (the position of the large mark 12 or the position of the small mark 14) at the four corners or at their vicinity is calculated as a height position Z0′ for searching for a mark.

In the setting height position for searching-for mark step (S105), the Z stage 108 is moved to control the height position of the target object 101 so that a calculated height position Z0′ may become a reference height position. As shown in FIG. 23, for example, regarding the surface height position of the mark stand 106 as a reference position, the target object 101 is moved in the z direction by the Z stage 108 so that the calculated height position Z0′ may be coincident with the reference height position.

In the roughly searching-for mark step (S112), in the state where the height position of the target object 101 has been controlled such that the height position Z0′ which is for searching for a mark becomes a reference height position, the Z sensor 220 scans a laser beam over a plurality of marks in such a manner that the laser beam intersects the plurality of marks. The contents of the third embodiment are the same as those of the first or second embodiment except that the height position of the target object 101 has been controlled such that the height position Z0′ which is for searching for a mark becomes a reference height position.

In the calculating mark position step (S114), in the state where the height position of the target object 101 has been controlled such that the height position Z0′ which is for searching for a mark becomes a reference height position, the first mark position calculation unit 58 calculates positions of a plurality of marks by using change of a signal for a mark of the plurality of marks due to a state of a surface of the target object 101, obtained by the Z sensor 220 by scanning a laser beam over the plurality of marks such that the laser beam intersects the plurality of marks. In other words, in the state where the height position of the target object 101 has been controlled such that the height position Z0′ which is for searching for a mark becomes a reference height position, the first mark position calculation unit 58 calculates, for each mark, the position of the mark concerned by using a height position distribution of the surface of the target object 101 for each mark, which is obtained by the Z sensor 220 by scanning a laser beam over a plurality of marks such that the laser beam intersects the plurality of marks. The contents of the third embodiment are the same as those of the first or second embodiment except that the height position of the target object 101 has been controlled such that the height position Z0′ which is for searching for a mark becomes a reference height position.

In the third embodiment, since, for example, the average of height positions of a plurality of marks is the height position Z0′ for searching for a mark and the height position Z0′ has been adjusted to be a reference height position, a difference Δh being a height deviation amount at each mark position deviated from the reference height position can be less than that in the case where the writing height position Z0 is adjusted to be a reference height position. Therefore, the positional deviation amount Δr resulting from deviation of the height position of the target object 101 can be a negligible small level (in an allowable range). Thus, even if the positional deviation amount Δr is not corrected, sufficient position accuracy can be obtained.

In the case of improving the accuracy of a mark position more highly, what is necessary is to perform the calculating positional deviation amount step (S115) and the correcting step (S117). When correcting, it operates as follows:

In the calculating positional deviation amount step (S115), the positional deviation amount calculation unit 60 calculates, for each mark, a positional deviation amount deviated from a calculated position of a mark concerned, by using an incident angle θ of a laser beam, and surface height positions of the target object 101 in the vicinity of at least a plurality of mark positions acquired when scanning a plurality of marks. Specifically, mark positions (the position of the large mark 12 or the small mark 14) at four corners, measured by the Z sensor 220 in the searching-for mark step (S101), or height positions at their vicinity are used. That is, a positional deviation amount Δr is calculated by using the difference Δh between the height of each mark position and the reference height position used when calculating the height position Z0′ for searching for a mark in the calculating height position for searching-for mark step (S103). For calculating the positional deviation amount Δr, the equation (1) may be used.

In the correcting step (S117), the correction unit 62 corrects, for each mark, a calculated position of the mark concerned, by using a calculated positional deviation amount Δr. The method of correction is the same as that of the correcting step (S118) in the first or second embodiment.

By the process described above, it is possible to obtain a mark position with high accuracy.

Here, since the height position Z0′ for searching for a mark has been adjusted as a reference height position in the target object 101, if as it is, the writing step (S140) cannot be carried out. Then, readjustment is performed to make the writing height position Z0 become a reference height position. Therefore, the measuring/calculating writing height position step (S120), the setting writing height position step (S122), and the acquiring writing height position distribution step (S124) are performed. The contents of each of the measuring/calculating writing height position step (S120), the setting writing height position step (S122), and the acquiring writing height position distribution step (S124) are the same as those of each of the measuring/calculating writing height position step (S102), the setting writing height position step (S104), and the acquiring writing height position distribution step (S106) of the first or second embodiment. Thereby, the height of the surface of the target object can be adjusted in the writing step (S140).

The contents of each of the scanning mark step (S126), the calculating (finely detecting) mark position step (S128), the generating shot data step (S130), the data processing step (S132), and the writing step (S140) are the same as those of each of the first or second embodiment.

Specifically, in the writing step (S140), in the state where the height position of the target object 101 has been controlled such that the writing height position Z0 (the second height position), which is set for writing, becomes a reference height position, the writing mechanism 150 writes a pattern on the target object 101 using the multiple beams 20, based on information on the position of each mark.

As described above, according to the third embodiment, since a mark position is measured in the state where a mark position obtained at the height position for searching for a mark, or a height position in its vicinity is regarded as a reference height, positional deviation of the mark position can be reduced. In the case of further performing correction, the accuracy can be further improved.

Embodiments have been explained referring to specific examples described above. However, the present invention is not limited to these specific examples. For example, a mark whose concave surface and convex surface are formed with different materials may be used.

While the apparatus configuration, control method, and others not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any other mark position measurement apparatus, mark position measurement method, charged particle beam writing apparatus, and charged particle beam writing method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A mark position measurement apparatus comprising:
a movable stage configured to mount thereon a target object on which a plurality of marks are formed;
a sensor configured to include an irradiator which irradiates the target object with a laser beam, and a receiver which receives a reflected light from the target object irradiated with the laser beam and outputs a signal relating to a height position of an irradiated position on a surface of the target object;
a height position distribution acquisition circuit configured to acquire, in a state where the height position of the target object has been controlled to be a predetermined height position, a height position distribution of the surface of the target object, based on a result obtained by the sensor;
a mark position calculation circuit configured to calculate, in a state where the height position of the target object has been controlled to be the predetermined height position, positions of the plurality of marks by using change of a signal for a mark of the plurality of marks due to a state of a surface of the target object, obtained by the sensor by scanning the laser beam over the plurality of marks such that the laser beam intersects the plurality of marks;
a positional deviation amount calculation circuit configured to calculate a positional deviation amount deviated from a calculated position of a mark concerned of the plurality of marks, by using an incident angle of the laser beam, and surface height positions of the target object at the positions of the plurality of marks acquired from the height position distribution of the surface of the target object; and
a correction circuit configured to correct, for the plurality of marks, the calculated position of the mark concerned by using a positional deviation amount concerned in a plurality of calculated positional deviation amounts.

2. The apparatus according to claim 1, wherein
the height position distribution acquisition circuit acquires, in a state where the height position of the target object has been controlled such that a writing height position, which is set for writing, becomes a reference height position, the height position distribution of the surface of the target object, based on the result obtained by the sensor, and
the mark position calculation circuit calculates, in the state where the height position of the target object has been controlled such that the writing height position, which is set for writing, becomes the reference height position, the positions of the plurality of marks by using a height position distribution of the surface of the target object for each mark of the plurality of marks, which is obtained by the sensor by scanning the laser beam over the plurality of marks such that the laser beam intersects the plurality of marks.

3. The apparatus according to claim 1, wherein
the sensor outputs height position information measured at a plurality of positions on the surface of the target object,
the height position distribution acquisition circuit calculates the height position distribution of the surface of the target object by a predetermined equation, by using the height position information at the plurality of positions on the surface of the target object, and
the positional deviation amount calculation circuit calculates, for each mark of the plurality of marks, the positional deviation amount by using a height position of a mark position concerned obtained by the predetermined equation.

4. The apparatus according to claim 1, wherein the positional deviation amount calculation circuit calculates the positional deviation amount deviated from the calculated position of the mark concerned, by using the incident angle of the laser beam, and surface height positions of the target object in a vicinity of at least the positions of the plurality of marks obtained in scanning the plurality of marks.

5. The apparatus according to claim 4, wherein the positional deviation amount calculation circuit calculates, for each mark of the plurality of marks, the positional deviation amount by using one of a plurality of height position information on a plurality of positions including a mark position concerned obtained in a range of scanning a mark concerned, and a plurality of height position information on a plurality of positions, excluding the mark position concerned obtained in the range of scanning the mark concerned.

6. A mark position measurement apparatus comprising:
a movable stage configured to mount thereon a target object on which a plurality of marks are formed;
a sensor configured to include an irradiator which irradiates the target object with a laser beam and a receiver which receives a reflected light from the target object irradiated with the laser beam and outputs a signal relating to a height position of an irradiated position on a surface of the target object;
a height position calculation circuit configured to calculate a first height position by using height position information, obtained by the sensor, on each position of positions where it is assumed that the plurality of marks exist;
a mark position calculation circuit configured to calculate, in a state where the height position of the target object has been controlled such that the first height position becomes a reference height position, positions of the plurality of marks by using change of a signal for a mark of the plurality of marks due to a state of a surface of the target object, obtained by the sensor by scanning the laser beam over the plurality of marks such that the laser beam intersects the plurality of marks; and
a control circuit configured to control, in order to write a pattern on the target object with a charged particle beam, the height position of the target object such that a second height position, which is set for writing, becomes the reference height position.

7. The apparatus according to claim 6, further comprising:
a positional deviation amount calculation circuit configured to calculate, for each mark of the plurality of marks, a positional deviation amount deviated from a calculated position of a mark concerned in the plurality of marks, by using an incident angle of the laser beam, and surface height positions of the target object in a vicinity of at least the positions of the plurality of marks obtained in scanning the plurality of marks; and
a correction circuit configured to correct, for the each mark, the calculated position of the mark concerned by using a calculated positional deviation amount.

8. A mark position measurement method comprising:
measuring, in a state where a height position of a target object, on which a plurality of marks are formed, mounted on a stage has been controlled to be a predetermined height position, height positions of a surface of the target object by a sensor including an irradiator which irradiates the target object with a laser beam and a receiver which receives a reflected light from the target object irradiated with the laser beam and outputs a signal relating to a height position of an irradiated position on the surface of the target object;
acquiring, a height position distribution of the surface of the target object, based on a result measured by the sensor;
calculating, in a state where the height position of the target object has been controlled to be the predetermined height position, positions of the plurality of marks by using change of a signal for a mark of the plurality of marks due to a state of a surface of the target object, obtained by the sensor by scanning the laser beam over the plurality of marks such that the laser beam intersects the plurality of marks;
calculating a positional deviation amount deviated from a calculated position of a mark concerned of the plurality of marks, by using an incident angle of the laser beam, and surface height positions of the target object at the positions of the plurality of marks acquired from the height position distribution of the surface of the target object; and
correcting, for the plurality of marks, the calculated position of the mark concerned by using a positional deviation amount concerned in a plurality of calculated positional deviation amounts, and outputting a corrected position of the mark concerned.

9. A mark position measurement method comprising:
measuring height position information on each position of positions, where it is assumed that a plurality of marks exist, on a target object which is mounted on a stage and on which the plurality of marks are formed, by a sensor including an irradiator which irradiates the target object with a laser beam and a receiver which receives a reflected light from the target object irradiated with the laser beam and outputs a signal relating to a height position of an irradiated position on a surface of the target object;
calculating a first height position by using the height position information, obtained by the sensor, on the each position of the positions where it is assumed that the plurality of marks exist;
calculating, in a state where a height position of the target object has been controlled such that the first height position becomes a reference height position, positions of the plurality of marks by using change of a signal for a mark of the plurality of marks due to a state of a surface of the target object, obtained by the sensor by scanning the laser beam over the plurality of marks such that the laser beam intersects the plurality of marks, and outputting calculated positions of the plurality of marks; and
controlling, in order to write a pattern on the target object with a charged particle beam, the height position of the target object such that a second height position, which is set for writing, becomes the reference height position.
